(19) United States
(12) Patent Application Publication
(10) Pub. No.: US 2014/0369392 A1
(43) Pub. Date: Dec. 18, 2014

(54) MULTI-STANDARD COMPATIBLE COMMUNICATION SYSTEM

(71) Applicant: ALCATEL-LUCENT USA INC., Murray Hill, NJ (US)

(72) Inventors: Sian Chong LEE, Summit, NJ (US); Noriaki KANEDA, Westfield, NJ (US)

(73) Assignee: ALCATEL-LUCENT USA INC., Murray Hill, NJ (US)

(21) Appl. No.: 13/916,969

(22) Filed: Jun. 13, 2013

(51) Int. Cl. H03M 1/02

(52) U.S. Cl. CPC H03M 1/02
USPC 375/216

(57) ABSTRACT

In one example embodiment, a communication system includes a remote unit configured to convert a plurality of signals, received at the remote unit from a plurality of end devices, into a plurality of first digital signals regardless of a bandwidth occupied by any of the plurality of signals. The communication system further includes a central unit configured to generate a plurality of second digital signals by processing the plurality of first digital signals received from the remote unit and transmit the plurality of second digital signals back to the remote unit, to be transmitted to the plurality of end devices.

### BACKGROUND

Nowadays, telecommunication standards are numerous and evolving rapidly (3G, 4G, Universal Mobile Telecommunication Systems (UMTS), Code Division Multiple Access (CDMA), Long Term Evolution (LTE), Data Over Cable Service Interface Specification (DOCSIS), WiFi, home network (G.hn), HomePlug, Multimedia over Coax Alliance (MoCa), etc.). It is very time-consuming and costly to develop application-specific hardware to keep up with and accommodate the numerous and rapidly-evolving standards. Implementation of ever-evolving telecommunication standards requires installment of hardware/equipment that are specifically configured for a given application or communication standard (Hereinafter, the terms communication standard and standard may be used interchangeably). For example, base stations that are installed as part of a GSM technology infrastructure cannot be used for transmission of Long Term Evolution (LTE) based signals. Given the highly-competitive telecommunication market, it is difficult to justify large investments for application specific hardware development every time a new standard is approved and brought into market.

It is therefore desirable to have a hardware which is flexible and configurable to support all different communication standards and uses software to configure, manage, and (de-)modulate the data associated with the various standards.

Current solutions include software-defined radio (SDR) and software radio access network (RAN). Such solutions are designed for and limited to transmitting digital baseband (Inphase and Quadrature), or digital intermediate frequency (IF) signals.

Furthermore, such solutions are focused entirely on wireless communication standards. Additionally, a large amount of hardware (FPGA, mixer, LO generator, etc.) is required in the remote unit (e.g., a base station). Many of these hardware components are specific to certain radio frequency bands and are neither very versatile in supporting other radio frequency bands nor non-wireless communication standards such as DOCSIS, G.hn, HomePlug, MoCa, etc.

### SUMMARY

Example embodiments relate to a system for implementing a multi-standard compatible communication system and/or a method of using the same. The multi-standard compatible communication system may include a plurality of remote units (e.g., base stations), each of which includes a minimal number of components necessary to receive, convert and transmit one or more signals received at any one of the plurality of remote units. These minimal components which are not customized for any specific communication standards, enable the remote units to convert any signal (e.g., from analog to digital and digital to analog), regardless of the communication standard based on which the one or more signals may have been transmitted (e.g., regardless of the bandwidth the one or more signals may occupy) to the plurality of remote units.

The multi-standard compatible communication system further includes a central unit in charge of performing signal processing functions. Upon receiving the converted signals at the central unit, the central unit, which is controlled by software implemented on a processor, performs further processing according to an appropriate one of a plurality of communication standards. Upon processing the signals, such signals may be transmitted back to the remote unit to be further converted and transmitted to intended end devices.

Performing the processing at the central unit allows the remote units to be more cost-effective and compatible with different communication standards because standard-specific components are no longer needed within the remote units for processing of signals. Moreover, such remote units can provide sufficient infrastructure to support multiple existing and/or to be developed communication standards and ultimately reduce associated costs.

In one example embodiment, a communication system includes a remote unit configured to convert a plurality of signals, received at the remote unit from a plurality of end devices, into a plurality of first digital signals regardless of a bandwidth occupied by any of the plurality of signals. The communication system further includes a central unit configured to generate a plurality of second digital signals by processing the plurality of first digital signals received from the remote unit and transmit the plurality of second digital signals back to the remote unit, to be transmitted to the plurality of end devices.

In yet another example embodiment, the remote unit is further configured to convert the plurality of signals into the plurality of first digital signals simultaneously using a single analog-to-digital converter.

In yet another example embodiment, the remote unit is further configured to convert the plurality of second digital signals into analog signals prior to transmission to the plurality of end devices.

In yet another example embodiment, the remote unit is further configured to convert the plurality of second digital signals into the analog signals simultaneously using a single digital-to-analog converter.

In yet another example embodiment, the analog-to-digital converter and the digital-to-analog converter have a resolution of at least 14 bits.

In yet another example embodiment, the plurality of signals received at the remote unit are associated with at least one of a plurality of wired communication standards and a plurality of wireless communication standards, the plurality of wireless communication standards including at least one of a 3G communication standard, a 4G communication standard, a Universal Mobile Telecommunication System (UMTS) communication standard, and a Code Division Multiple Access (CDMA) communication standard.

In yet another example embodiment, the remote unit and the central unit communicate via at least one of a wired communication link and a wireless communication link.

In yet another example embodiment, the central unit is further configured to process the plurality of first digital signals by performing at least one of a digital signal processing, a media access control and a routing of the plurality of first digital signals to intended destinations.

In yet another example embodiment, the remote unit is a base station.

In one example embodiment, a remote unit is configured to convert a plurality of signals received at the remote unit into a plurality of first digital signals, regardless of a bandwidth occupied by any of the plurality of signals. The remote unit is further configured to transmit the plurality of first digital signals to a central unit, receive a plurality of second digital signals back from the central unit upon the central unit having processed the plurality of first digital signals, and transmit the plurality of second digital signals to a plurality of end devices.

In yet another example embodiment, the remote unit does not include a hardware customized according to any given communication standard.

In one example embodiment, a central unit includes a processor configured to receive a plurality of first digital signals from a remote unit. The processor is further configured to determine one of a plurality of communication standards according to which any one of the plurality of first digital signals is to be processed. The processor is further configured to enable processing of the one of the plurality of first digital signals based on the determined one of the plurality of communication standards.

In yet another example embodiment, the processor is further configured to determine one of the plurality of communications standards by enabling at least one of a modulation and demodulation of the plurality of first digital signals by the digital signal processing unit of the central unit, and the processing includes at least one of a media access control and a routing of the plurality of first digital signals to intended destinations, by a central processing unit of the central unit.

In yet another example, the processor is further configured to generate a plurality of second digital signals based on the processing of the plurality of first digital signals, the plurality of second digital signals being transmitted back to the remote unit for further transmission to end devices.

### BRIEF DESCRIPTION OF THE DRAWINGS

Example embodiments will become more fully understood from the detailed description given herein below and the accompanying drawings, wherein like elements are represented by like reference numerals, which are given by way of illustration only and thus are not limiting of the present disclosure, and wherein:

FIG. 1 illustrates an environment in which the multi-standard compatible communication system may be implemented, according to an example embodiment;

FIG. 2 illustrates the components of the multi-standard compatible communication system, according to an example embodiment;

FIG. 3 is a flow chart describing a process based on which a remote unit of the multi-standard compatible communication system operates, according to an example embodiment; and

FIG. 4 is a flow chart describing a process based on which a central unit of the multi-standard compatible communication system operates, according to an example embodiment.

### DETAILED DESCRIPTION OF EXAMPLE EMBODIMENTS

Various embodiments will now be described more fully with reference to the accompanying drawings. Like elements on the drawings are labeled by like reference numerals.

Detailed illustrative embodiments are disclosed herein. However, specific structural and functional details disclosed herein are merely representative for purposes of describing example embodiments. This invention may, however, be embodied in many alternate forms and should not be construed as limited to only the embodiments set forth herein.

Accordingly, while example embodiments are capable of various modifications and alternative forms, the embodiments are shown by way of example in the drawings and will be described herein in detail. It should be understood, however, that there is no intent to limit example embodiments to the particular forms disclosed. On the contrary, example embodiments are to cover all modifications, equivalents, and alternatives falling within the scope of this disclosure. Like numbers refer to like elements throughout the description of the figures.

Although the terms first, second, etc. may be used herein to describe various elements, these elements should not be limited by these terms. These terms are only used to distinguish one element from another. For example, a first element could be termed a second element, and similarly, a second element could be termed a first element, without departing from the scope of this disclosure. As used herein, the term “and/or,” includes any and all combinations of one or more of the associated listed items.

When an element is referred to as being “connected,’ or “coupled,” to another element, it can be directly connected or coupled to the other element or intervening elements may be present. By contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting. As used herein, the singular forms “a”, “an”, and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Specific details are provided in the following description to provide a thorough understanding of example embodiments. However, it will be understood by one of ordinary skill in the art that example embodiments may be practiced without these specific details. For example, systems may be shown in block diagrams so as not to obscure the example embodiments in unnecessary detail. In other instances, well-known processes, structures and techniques may be shown without unnecessary detail in order to avoid obscuring example embodiments.

In the following description, illustrative embodiments will be described with reference to acts and symbolic representations of operations (e.g., in the form of flow charts, flow diagrams, data flow diagrams, structure diagrams, block diagrams, etc.) that may be implemented as program modules or functional processes include routines, programs, objects, components, data structures, etc., that perform particular tasks or implement particular abstract data types and may be implemented using existing hardware at existing network elements. Such existing hardware may include one or more Central Processing Units (CPUs), digital signal processors (DSPs), application-specific-integrated-circuits, field programmable gate arrays (FPGAs), computers or the like.

Although a flow chart may describe the operations as a sequential process, many of the operations may be performed in parallel, concurrently or simultaneously. In addition, the order of the operations may be re-arranged. A process may be terminated when its operations are completed, but may also have additional steps not included in the figure. A process may correspond to a method, function, procedure, subroutine, subprogram, etc. When a process corresponds to a function, its termination may correspond to a return of the function to the calling function or the main function.

As disclosed herein, the term “storage medium” or “computer readable storage medium” may represent one or more devices for storing data, including read only memory (ROM), random access memory (RAM), magnetic RAM, core memory, magnetic disk storage mediums, optical storage mediums, flash memory devices and/or other tangible machine readable mediums for storing information. The term “computer-readable medium” may include, but is not limited to, portable or fixed storage devices, optical storage devices, and various other mediums capable of storing, containing or carrying instruction(s) and/or data.

Furthermore, example embodiments may be implemented by hardware, software, firmware, middleware, microcode, hardware description languages, or any combination thereof. When implemented in software, firmware, middleware, or microcode, the program code or code segments to perform the necessary tasks may be stored in a machine or computer readable medium such as a computer readable storage medium. When implemented in software, a processor or processors will perform the necessary tasks.

A code segment may represent a procedure, function, subprogram, program, routine, subroutine, module, software package, class, or any combination of instructions, data structures or program statements. A code segment may be coupled to another code segment or a hardware circuit by passing and/or receiving information, data, arguments, parameters or memory contents. Information, arguments, parameters, data, etc. may be passed, forwarded, or transmitted via any suitable means including memory sharing, message passing, token passing, network transmission, etc.

Example embodiments may be utilized in conjunction with RANs such as: Universal Mobile Telecommunications System (UMTS); Global System for Mobile communications (GSM); Advance Mobile Phone Service (AMPS) system; the Narrowband AMPS system (NAMPS); the Total Access Communications System (TACS); the Personal Digital Cellular (PDC) system; the United States Digital Cellular (USDC) system; the code division multiple access (CDMA) system described in EIA/TIA IS-95; a High Rate Packet Data (HRPD) system, Worldwide Interoperability for Microwave Access (WiMAX); Ultra Mobile Broadband (UMB); and 3^{rd} Generation Partnership Project LTE (3GPP LTE).

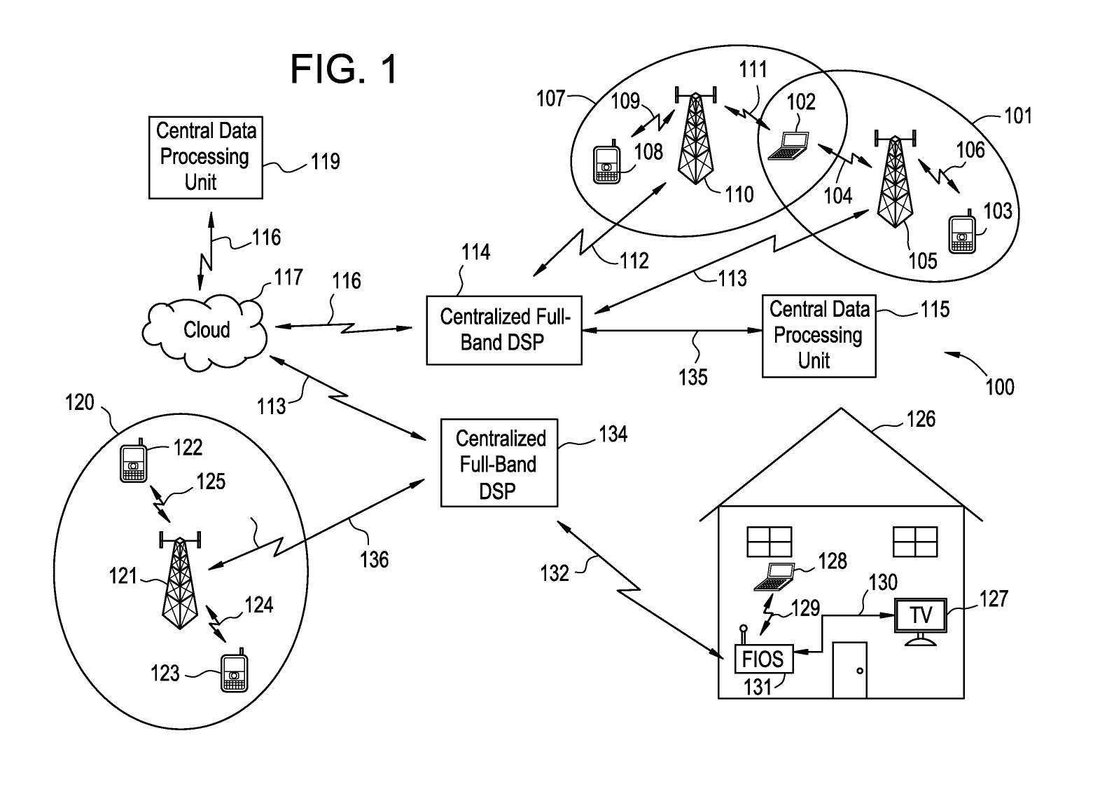

FIG. 1 illustrates an environment in which the multi-standard compatible communication system may be implemented, according to an example embodiment. FIG. 1 depicts an environment 100 in which one example embodiment of a multi-standard compatible communication system may be implemented. The multi-standard compatible communication system may comprise of at least one remote unit, a centralized full-band digital signal processing (DSP) unit and a centralized data processing unit, as will be further described below.

The environment 100 may include a plurality of sub-environments, in each of which a plurality of devices operate according to different communication standards. Each sub environment may be served by one or more remote units (e.g., base stations) such as remote units 105, 110, 121 and 131, as shown in FIG. 1. The plurality of devices may be any one of, but not limited to, a mobile phone, a computer including a laptop computer or a desktop, any type of handheld device capable of communicating and exchanging data, a multimedia entertainment device such as a TV, an internet-enabled audio/video system, etc.

For example, the sub-environment 101 may include devices 102 and 103, where device 102 is a laptop capable of communicating with the remote unit 105 via a WiFi connection. Such WiFi connection may be a wireless connection 104. In one example embodiment, the connection 104 may be wired, through which the laptop 102 communicates with remote unit 105 (e.g., a wired internet connection such as a DSL cable). Meanwhile, device 103 is a cellular phone, which may be 4G enabled and operate based on the LTE communication standard. Device 103 may communicate an LTE based signal to the remote unit 105 via a wireless connection 106.

The environment 100 may further include a sub-environment 107, which may partially overlap the sub-environment 101. For example, the device 102 may be able to communicate with both the remote unit 105 of sub-environment 1 and the remote unit 110 of sub-environment 107. Device 103 may communicate a wireless WiFi signal to remote unit 107 via a wireless connection 111. In another example embodiment, the connection 111 may be wired and similar to the connection 104, as described above. Sub-environment 107 may further include a mobile device 108, which operates according to the CDMA communication standard. Device 108 may communicate a CDMA based signal to the remote unit 107 via a wireless connection 109.

In yet another example embodiment, the environment 100 may further include a sub-environment 120. The sub-environment 120 may include the remote unit 121, with which devices 122 and 123 communicate. Device 122 may operate based on the GSM communication standard. Device 122 may communicate a GSM based signal to the remote unit 121 via a wireless connection 125. The device 123 may be a GSM and/or CDMA based device which may be 4G enabled thus communicating a LTE based signal, via the wireless communication 124, to the remote unit 121.

In yet another example embodiment, the environment 100 may further include a sub-environment 126, which may be any one of, but not limited to, a residential place, a business place, a public location such as a library or a museum, etc. The sub-environment 126 may include a plurality of devices operating based on Multimedia over Coaxial Alliance (MoCA) technology. For example, a multimedia system within the sub-environment 126 or components thereof, e.g., TV 127, may communicate a signal via the cable 130 to a cable box, such as FIGS cable/modem box 131. There may further be wireless communication enabled devices within the sub-environment 126. For example, a laptop such as laptop 128 may communicate an analog WiFi signal via the wireless communication link 129 to the FIGS cable/modem box 131.

As can be seen from FIG. 1, remote units 105, 110, 121 and 131 communicate the signals received from any of the described devices to a centralized full-band DSP such as centralized full-band DSPs 114 and 134. In one example embodiment, such signals are converted from analog signals into digital signals prior to being transmitted from the remote units to any of the centralized full-band DSPs 114 and 134. Such communication between the remote units 105, 110, 121, and 131, and the centralized full-band DSPs 114 and 134 may be enabled via wireless and/or wired communication links 112, 113, 132 and 136.

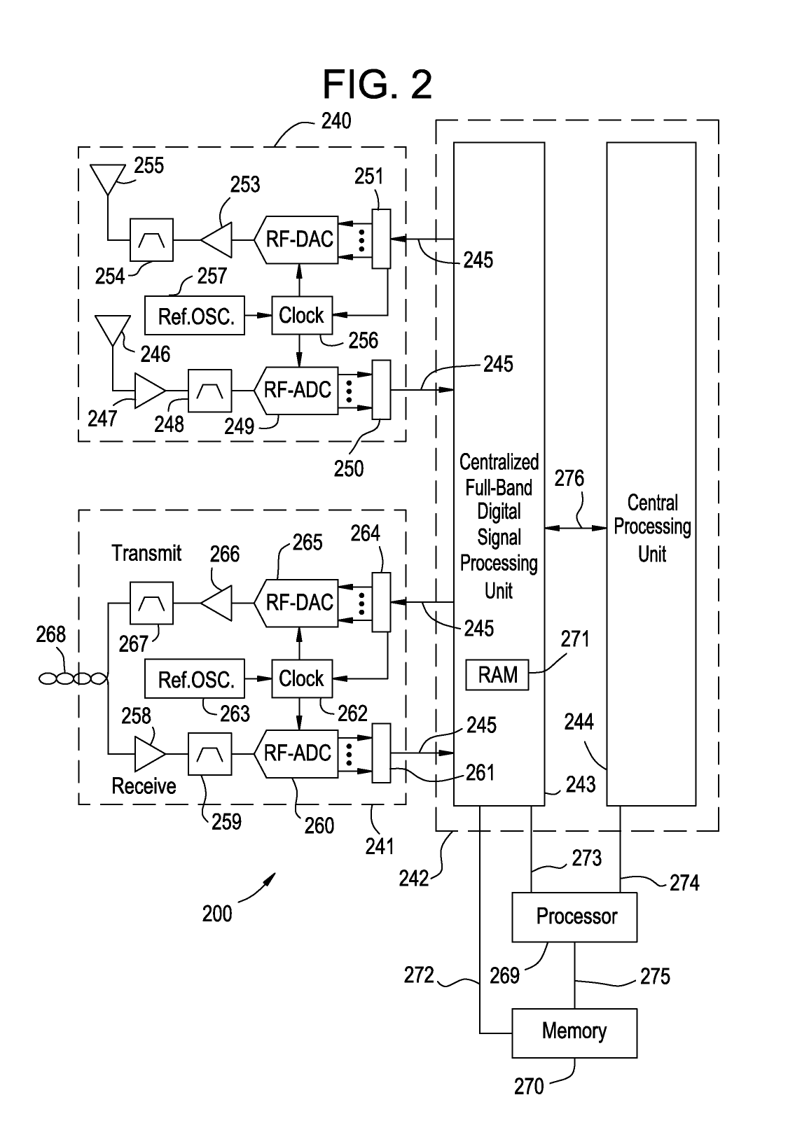

As will be described further below with respect to FIGS. 2-4, the analog signals received from the devices at the remote units may be converted into digital signals prior to transmission to the centralized full-band DSPs. The centralized full-band DSPs 114 and 134 may further communicate with a central data processing unit such as central data processing units 115 and 119. The centralized full-band DSPs 114 and 134 may be co-located in one physical location with the central data processing units 115 and 119, where, for example the communication between the centralized full-band DSP 114 and the central data processing unit 115 may be established via a communication link 135. The communication link 135 may be either wired or wireless. Alternatively, the centralized full-band DSPs 114 and 134 may further communicate with the central data processing units 115 and 119 over a cloud 117 (e.g., public internet). Such communication may be made via a communication link such as communication link(s) 116. The communication link(s) 116 may include a wireless communication links and/or a wired communication links (e.g., fiber optics cables). Furthermore, the communications between the remote units (105, 110, 121 and 131), the centralized full-band DSPs (114 and 134), and the central data processing units (115 and 119) may be bi-directional.

FIG. 2 illustrates the components of the multi-standard compatible communication system, according to an example embodiment. The multi-standard compatible communication system 200 may include one or more remote units such as remote units 240 and 241, which may correspond to any one of the remote units 105, 110, 121 and 131 of FIG. 1, described above. In one example embodiment, the remote units may be base stations.

As discussed in the Background Section, some of the current solutions, require a relatively significant amount of standard-specific hardware components inside the remote units, including but not limited to, FPGAs, mixers, LO generators, etc. Many of such hardware components are customized for a given standard (e.g., customized for CDMA communication standard, GSM communication standard, MoCa communication standard, UMTS communication standard, etc.). As a result, such remote units may not be used to receive/transmit signals which do not belong to a communication standard with which any of the remote units are customized.

Moreover, current solutions digitize only the baseband data. For example, if a given communication standard occupies the 2.5-2.75 GHz bandwidth, current remote units include customized hardware that are only capable of digitizing signals that contain data within the 2.5-2.75 GHz bandwidth. Therefore, another signal that is received but falls outside of such specific bandwidth may not be processed by the remote unit.

In contrast, as discussed above, the remote units 240/241 may include a minimal number of components that are not specific to any particular communication standard. For example, by using a high-speed/high resolutions analog-to-digital converters and digital-to-analog converters, an entire bandwidth of such high-speed/high resolution converters may be digitized. Therefore, any signal transmitted to the remote unit, which occupies a bandwidth that falls within the bandwidth of the converters, is digitized. As a result, a remote unit capable of receiving signals occupying different bandwidths (e.g., belong to different communication standards) is obtained. Furthermore, due to the use of the high-speed/high resolutions converters, signals belonging to different communication standards can simultaneously be converted, thus providing a more efficient communication system. The remote unit(s) 240/241 will be further described below.

As illustrated in FIG. 2, remote unit 240 may be capable of receiving and transmitting wireless signals, while remote unit 241 may be capable of receiving and transmitting signals over wired lines, where wired lines may be any one of, but not limited to, a twisted pair cable, a coaxial cable, a fiber optic cable, etc. Alternatively, remote units 240 and 241 may be combined into a single remote unit capable of receiving and transmitting signals both wirelessly and over a wired line. For example, remote unit 131, illustrated in FIG. 1 and described above, may be used to receive and transmit signals to/from TV station 127 over a cable, while at the same time, the remote unit 131 may be able to wirelessly transmit and receive signals to/from laptop 128 and/or the centralized full-band DSP 134.

The remote units 240 and 241 may communicate with a central unit 242. The central unit 242 may include a centralized full-band DSP unit 243 and a central data processing unit 244. As described above, the centralized full-band data DSP unit 243 and the central data processing unit 244 may be co-located in a same physical location or alternatively may be located in different locations, in which case they may communicate via 276 wirelessly over a network or through a wired connection such as co-axial cables, fiber optic cables, etc.

Furthermore, the remote units 240 and 241 may be co-located in the same physical location with the central unit 242 or may communicate with the central unit via a network and or links 245. The remote units 240 and 241 may communicate with the central unit 242 via communication links 245, which may correspond to any of the links 112, 113, 132 and 136 illustrated in FIG. 1. The communication links 245 may be a single high capacity link capable of transmitting data at high rates including, but not limited to, up to 100 Giga bits per second (Gbps). The communication links 245 may further include multiple links, where each link is capable of only communicating data at lower rates (e.g., 10 Gbps). However, such multiple communication links together may enable data transmission at higher rates (e.g., 10 10 Gbps cables to transmit data at 100 Gbps).

The remote unit 240 may include a receiving antenna 246, through which one or more signals (e.g., analog signals) may be received from devices such as those depicted in FIG. 1 (e.g., 102, 103, 108, 122, 123, 127, 128, etc.). The remote unit 240 may further include an amplifier 247 for amplifying the one or more received signal so that noise is minimized and the signal amplitude is suitable and/or optimized for correct/non-erratic reception by further processing elements within a communication system such as the system 200, as will be further described below. The remote unit 240 may further include a filter 248, which may be utilized to recover the one or more received signals (e.g., remove noise, etc.). The filter 248 may be a low pass filter. The filter 248 may be utilized to address conversion issues including, but not limited to, aliasing, mirror images, noise, etc. The bandwidth of this filter may be as large as the entire bandwidth of an analog-to-digital converter or a digital-to-analog converter, as will be described below.

The remote unit 240 may further include an analog-to-digital converter (ADC) 249, which is used to convert the one or more received signals into digital signal(s) to be transmitted to the central unit for further processing. In one example embodiment, the ADC may be a high-speed/high resolution ADC with a 14 bit resolution. Alternatively, ADCs with higher or lower resolutions may be utilized as the ADC 249. In one example embodiment, the ADC 249 may digitize the one or more signals that cover an entire analog band-width of the ADC 249. For example, if the analog bandwidth of the ADC 249 is 0-5 GHz, then a received analog signal that covers the entire 0-5 GHz bandwidth will be digitized by the ADC 249. In one example embodiment, even when the received analog signal covers only part of the 0-5 GHz bandwidth (e.g., 2.25-2.75 GHz), still the entire 0-5 GHz will be digitized. Such digitization of an entire analog bandwidth of the ADC 249 provides an ability to support a variety of communication standards (e.g., both GSM and LTE standards as each standard occupies a different bandwidth for communicating signals).

In yet another example embodiment, if multiple signals which occupy different bandwidth within the entire bandwidth of the ADC 249, are received at the remote unit(s) 240/241, the ADC 249 can simultaneously digitize these signals, because the entire 0-5 GHz is being digitized.

The ADC 249 is further in communication with a clock 256, which is responsible for synchronizing the ADC 249 and a digital-to-analog (DAC) 252, which will be further described below. The clock may be generated by a reference oscillator 257.

The remote unit 240 may further include an interface 250. In one example embodiment and in which a single high capacity link is used to transmit multiple digitized outputs of ADC 249 to the central unit 242, the interface 250 may be a serializer for combining all the digitized signals for transmission over a single communication link, such as the high capacity communication link 245.

The interface 250 may further be configured to determine reliability and synchronization of signals that are to be transmitted to the central unit 242. In one example embodiment, the interface 250 analyzes the signal to be transmitted, for error and/or signal corruption. In case of signal corruption and/or errors, the interface 250 may detect and/or require retransmission of signals from a device from which the signal was received. Alternatively, the interface 250 may detect and/or correct any error in the signal received at the interface 250. In one example embodiment, the interface 250 may have been pre-programmed with a maximum allowable error-rate for proper functioning and the error detection may be based on such maximum allowable error-rate. The interface 250 may further perform functions including, but not limited to, skew alignment, framing/de-framing, etc. The interface 250 may be any one of, but not limited to, a common public radio interface (CPRI), an Ethernet, an Interlaken, etc.

The remote unit 240 further includes a second interface 251. In one example embodiment and in which a single high capacity link is used to transmit multiple digital signals, processed by the central unit 242, from the central unit 242 to the remote unit 240, the interface 251 may be a de-serializer for decomposing the combined signals into multiple signals to be transmitted from the remote unit 240 to the intended devices (e.g., devices 102, 103, etc., depicted in FIG. 1).

The interface 251 may further be configured to determine reliability and synchronization of the processed signals received from the central unit 242. In one example embodiment, the interface 251 may be enabled to analyze the received signal for error and/or signal corruption. In case of signal corruption and/or errors, the interface 251 may require the central unit to retransmit the transmitted signals. The interface 251 may further perform functions including, but not limited to, skew alignment, framing/de-framing and clock recovery. The interface 251 may be the same and/or function in a similar manner as interface 250. The interface 251 may further be in communication with the clock 256 such that the recovered clock of the received signals may be used in synchronizing the clocks of the ADC 249 and DAC 252.

The remote unit 240 may further include the DAC 252, which is used to convert the processed digital signal(s) received from the central unit 242, into analog signal(s).

Similar to ADC 249, in one example embodiment, if multiple processed digital signals, which occupy different bandwidth within the entire bandwidth of the DAC 252, are received at the remote unit(s) 240/241, the DAC 252 can simultaneously convert the signals into analog signals for transmission to the end devices.

In one example embodiment, ADC 249 and DAC 252 have the same bandwidth.

As explained above, DAC 252 may further be in communication with the clock 256 for synchronization purposes. The converted signal(s) may then be amplified for transmission purposes via the amplifier 253. Thereafter, the remote unit 240, via a filter 254, may perform appropriate filtering on the amplified signals, as described above with respect to filter 248. The amplified signal(s) is thereafter transmitted to intended devices (e.g., devices 102, 103, etc., as shown in FIG. 1) via a transmitting antenna 255.

The remote unit 241 and the components 258-261, 262-263 and 264-267 function in the same manner as components 247-250, 256-257 and 251-255, respectively, described above with regard to remote unit 240. Remote units 240 and 241 operate in the same manner except that remote unit 241 does not include the wireless receiving/transmitting antennas 246 and 255 of the remote unit 240 and instead includes a wired communication link 268. The remote unit 241 receives/transmits signals via the wired communication link 268, which as described above may be any one of, but not limited to, a coaxial cable, a twisted pair cable, a fiber optics cable, etc.

The central unit 242 of the communication system 200 further includes a centralized full-band DSP unit 243 and a central data processing unit 244. The exchange of data between the centralized full-band DSP unit 243 and the central data processing unit 244 is enabled via the communication link 276. The communication link 276 may be wired or wireless. The centralized full-band DSP unit 243, upon receipt of digitized signals from the remote units 240 and 241, may perform various digital signal processing functions on the received signals, including, but not limited to, functions corresponding to a physical layer of the Open System Interconnection (OSI) model (e.g., OSI layer-1). Such functions include, but are not limited to signal modulation/demodulation. The centralized full-band DSP unit 243 may be controlled by a processor 269 via a communication link 273, which may be wired or wireless.

In one example embodiment, the processor may pull appropriate processing functions from a memory 270 for processing a received digital signal. The memory 270 may store processing functions associated with different communication standards to be utilized by the centralized full-band DSP unit. For example, upon receiving a digitized CDMA based signal from the remote unit(s) 240/241, the processor 269 may retrieve functions that are specific to processing CDMA signals from the memory 270. The processor 269 may communicate with the memory 270 via a communication link 275, which may be wired or wireless.

The retrieved processing functions may be stored in a RAM 271 of the centralized full-band DSP unit 243 for use/retrieval by the centralized full-band DSP unit 243. The memory 270 may be in communication with the centralized full-band DSP 243 via the communication link 272, which may be wired or wireless.

The central data processing unit 244 may perform further back-end processing including, but not limited to, signal routing, media access control (MAC), and higher layer processing, such as processing functions corresponding to layers 2-7 of OSI model. The central processing unit 244 may also be controlled and directed by the processor 269, via the communication link 274, to carry out the functions described above. The communication link 274 may be wired or wireless. In one example embodiment, the processor 269 and the memory 270 are incorporated into the central data processing unit 244.

The centralized full-band DSP unit 243, the central data processing unit 244, the processor 269 and the memory 270 may be co-located in the same physical location(s) or may alternatively be located in separate physical locations, in which case the communication links, 272-276 may be wireless communication links.

In one example embodiment, the centralized full-band DSP unit 243 may not perform in any standard-specific processing but may rather perform non-standard-specific processing of signals received at the central unit 242 including, but not limited to, signal filtering, up/down conversion of the signal, up/down sampling of the signals, etc.

Thereafter, the processor 269, via the central processing unit 244, may determine additional centralized full-band DSP units (not shown). The additional centralized full-band DSP units are specific to a given communication standard (standard-specific centralized full-band DSP units), to which the signal received at the central unit may be forwarded for further standard-specific processing.

For example, when a CDMA signal and a MoCa based signal digitized at the remote unit(s) 240/241 are received at the central unit 242, the processor 269, via the centralized full-band DSP unit 243, may perform signal processing of the received signals, where such processing is non-standard-specific and can be performed on signals transmitted based on different communication standards. Thereafter, the centralized full-band DSP unit 243 may forward the signals to the central processing unit 244. The processor 269, via the central processing unit 244, may locate a CDMA specific centralized full-band DSP unit, which performs processing specific to CDMA communication standard, and thus may forward the CDMA based signal to such CDMA specific centralized full-band DSP unit. Furthermore, the processor 269, via the central processing unit 244, may locate a MoCa specific centralized full-band DSP unit, which performs processing specific to MoCa communication standard, and thus may forward the MoCa based signal to such MoCa specific centralized full-band DSP unit.

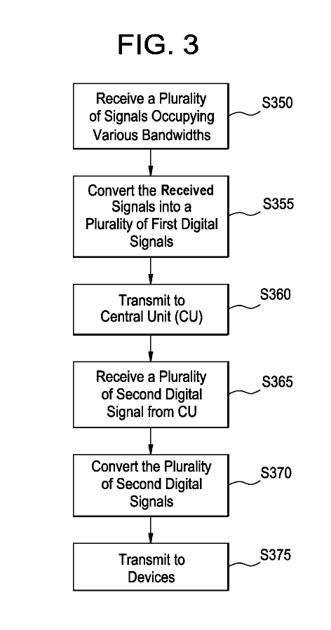

FIG. 3 is a flow chart describing a process based on which a remote unit of the multi-standard compatible communication system operates, according to an example embodiment. At S350, the remote unit(s) 240/241 receives a plurality of signals which may have been sent by one or more end devices, such as devices 102, 103, 108, 122, 123, 127 and 128, described above with respect to FIG. 1. The plurality of signals may be received via an antenna such as the wireless receiving antenna 246 and/or the cable 268, illustrated and described above with respect to FIG. 2. The plurality of signals may occupy different bandwidths. For example, one of the received signal may occupy a bandwidth of 2.25-2.75 GHz, while another received signal may occupy a bandwidth of 0.9-1.2 GHz.

At S355, the remote unit(s) 240/241 convert the received signals into a first plurality of digital signals. For example, the remote unit(s) 240/241 may perform a digitization of the plurality of signals received at S350. Prior to digitization of the plurality of signals, the remote unit(s) 240/241 may perform further tasks such as amplifying the plurality of received signals, band-pass filter the plurality of received signals, etc. As described above, the digitization of the plurality of received signals may be performed via a ADC such as ADC 249. Also, as described above, the digitization of the plurality of received signals may be done by digitizing an entire bandwidth of the ADC 249. Because each of the signals occupy different bandwidths within the entire bandwidth of the ADC 249 converter, all of the signals are digitized regardless of the bandwidth they occupy (e.g., regardless of the communication standard according to which the plurality of signals have been transmitted to the remote unit(s) 240/241. In one example embodiment, the ADC 249 may have a resolution of 14-bits or more.

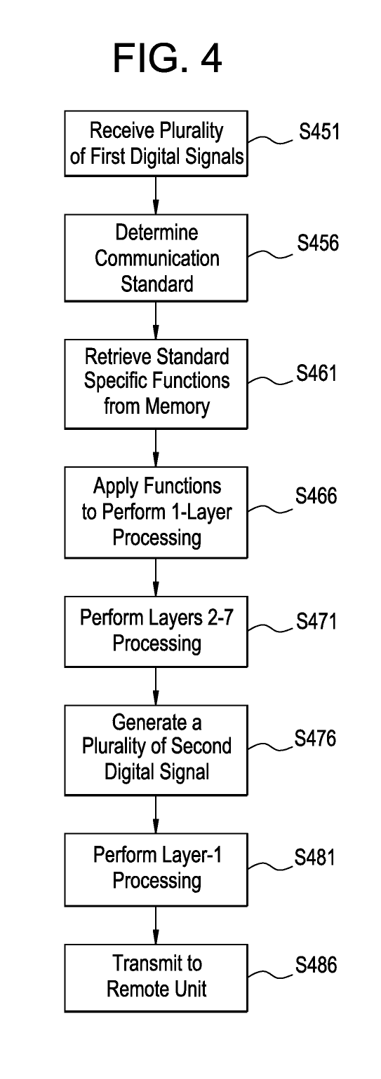

At S360, the remote unit(s) 240/241 transmit the aligned/framed plurality of first digital signals to the central unit 242 of FIG. 2. Once the central unit 242 perform the task of processing the received plurality of first digital signals, which will be further described with respect to FIG. 4 below, the remote unit(s) 240/241 receive a plurality of second digital signals back from the processing unit 242 at S365.

The plurality of second digital signals may be a processed version of the plurality of first digital signals transmitted to the central unit 242, at S360. Alternatively, the plurality of second digital signals may be signals different from the plurality of first digital signal but generated in response to the processing of the plurality of first digital signals.

Prior to transmission at S360, the remote unit(s) 240/241, via an interface such as interface 250 of FIG. 2, may perform tasks including, but not limited to, signal framing and data alignment on the plurality of first digital signals, as described above with respect to FIG. 2.

Referring to FIG. 4, FIG. 4 is a flow chart describing a process based on which a central unit of the multi-standard compatible communication system operates, according to an example embodiment. At S451, the processing unit may receive a plurality of first digital signals transmitted to the central unit 242 by the remote unit(s) 240/241.

At S456, the processor 269, may determine the appropriate communication standard, with which any of the received plurality of first digital signals may be associated. At S461, the processor 269 may retrieve processing functions associated with the determined communication standard from the memory 270 and load the same onto the RAM 271 of the centralized full-band DSP unit 243.

In one example embodiment, the remote unit 240 may be configured to receive both a CDMA based signal as well as a MoCa based signal. Such configuration of a given remote unit (e.g., remote unit 240) may be stored in a memory, which may be the same as memory 270 or may be a separate memory in communication with the processor 269 (not shown). Upon receiving a signal at the central unit from the remote unit 240, the processor retrieves demodulation processes and/or algorithms corresponding to possible communication standards according to which the received signal is transmitted (e.g., CDMA or MoCa). Such standards may then be loaded onto the centralized full-band DSP unit 243 and the received signal may be demodulated according to the retrieved communication standards (e.g., CDMA or MoCa). Because a signal transmitted based on different communication standards, occupy different bandwidths, when such signals are demodulated based on communication standards other than one based on which the signal has been transmitted, no output is provided. For example, when a MoCa signal is demodulated using a CDMA based demodulation process and/or algorithm, the results of the demodulation may provide useless data and/or noise. Therefore, in the example embodiment described above, the processor 269 may determine the appropriate communication standard based on the outcome of demodulators applied to a given received signal.

At S466, the processor 269, via the centralized full-band DSP unit 243, may apply the retrieved functions to a corresponding one of the plurality of first digital signals received at the central unit 242. In one example embodiment, such functions, as described above, may include OSI model layer-1 functions (e.g., demodulation of the received signals).

At S471, the processor 269, via the central processing unit 244, may perform further back-end processing on the plurality of first digital signals including, but not limited to, signal routing, media access control (MAC), and higher layer processing such as processing/functions associated with OSI model layers 2-7 processing. At S476, the processor 269 may generate a plurality of second digitals signals, which as described above, may be a processed version of the plurality of first digital signals or alternatively may be a new set of signals generated in response to the processing at S466-S471.

At S481, upon completion of the back-end processing by the central processing unit 244, the processor 269 via the centralized full-band DSP 243 may once again perform OSI model layer-1 functions. However, in contrast to the OSI model layer-1 function performed at S466, at S476, the OSI layer-1 includes modulation of the plurality of second digital signals using the central processing unit. At S486, the central unit 242 may transmit the modulated plurality of second digital signals back to the remote unit(s) 240/241.

In yet another example embodiment and in which the centralized full-band DSP unit 243 performs only non-standard-specific processing as described above, steps S456-S481 may be modified as follows. At S456, the processor 269, via the centralized full-band DSP unit 243 perform non-standard-specific signal processing on the received plurality of first digital signals including, but not limited to, up/down sampling of signals, up/down conversion of signals, filtering, etc.

At S461, the processor 269, via the central processing unit 244, may determine the communication standard associated with each signal of the plurality of first digital signals received at the central unit 242. At S466, signals may be forwarded to standard-specific centralized full-band DSP units (e.g., a CDMA signal may be forwarded to a CDMA specific centralized full-band DSP unit).

In one example embodiment, the processor 269 may transmit the signal to every standard-specific centralized full-band DSP (e.g., both CDMA and MoCa specific centralized full-band DSPs), depending on the configuration of the remote unit from which the signal has been received, as described above. Such transmission to standard-specific centralized full-band DSPs may be done simultaneously or one at a time. The central processing unit 243 may then await a response from the standard-specific centralized full-band DSPs. The central processing unit 243 may receive a response from one of the standard-specific centralized DSPs, which corresponds to the communication standard to which the signal belongs.

At S471, the processor 269, via the central processing unit 244, may receive the signals back from one or more standard-specific centralized full-band DSP units. At S476, a plurality of second digital signals may be generated as a result of the processing at S466-S471.

At S481, the plurality of second digital signals may be modulated by the processor 269, via the centralized full-band DSP unit 243. S481 remains the same as described above.

Referring back to FIG. 3, at S365, the remote unit receives the plurality of second digital signals from the central unit 242. Upon receiving the plurality of second digital signals back from the central unit 242, the remote unit(s) 240/241, via an interface such as interface 251 of FIG. 2, perform tasks including, but not limited to, data alignment, signal framing and clock recovery, also described above with respect to FIG. 2. At S370, the remote unit(s) 240/241 may convert the plurality of second digital signals, into a plurality of analog signals for transmission to one or more end devices. The remote unit(s) 240/241 may perform the conversion, described above with respect to FIG. 2, using a high resolution DAC (e.g., DAC 252) with a resolution of, for example 14 bits. However, other DACs with lower or higher resolutions may also be employed to carry out the conversion.

As described above, multiple signals occupying different bandwidths over the bandwidth of DAC 252, may be digitized simultaneously, because the entire bandwidth of DAC 252 is digitized. In one example embodiment, DAC 252 and ADC 249 have the same bandwidth.

At S375, the remote unit(s) 240/241 may transmit the plurality of analog signals to the intended end devices, such as devices 102, 103, 108, 122, 123, 127 and 128, as described above with respect to FIG. 1. The remote unit(s) 240/241 may transmit the plurality of analog signals via a transmitting antenna such as antenna 255 or the cable 268, illustrated and described above with respect to FIG. 2.

After the conversion of the signal at S370 and prior to transmitting the same at S375, the remote unit(s) 240/241 may amplify the plurality of analog signals and/or band-pass filter the plurality of analog signals for purposes of achieving a more reliable transmission of the signal to the end device(s).

Variations of the example embodiments are not to be regarded as a departure from the spirit and scope of the example embodiments, and all such variations as would be apparent to one skilled in the art are intended to be included within the scope of this disclosure.

What is claimed:

1. A communication system, comprising:
a remote unit configured to convert a plurality of signals, received at the remote unit from a plurality of end devices, into a plurality of first digital signals regardless of a bandwidth occupied by any of the plurality of signals; and
a central unit configured to,
generate a plurality of second digital signals by processing the plurality of first digital signals received from the remote unit, and
transmit the plurality of second digital signals back to the remote unit, to be transmitted to the plurality of end devices.

2. The communication system of claim 1, wherein the remote unit is further configured to convert the plurality of signals into the plurality of first digital signals simultaneously using a single analog-to-digital converter.

3. The communication system of claim 2, wherein the remote unit is further configured to convert the plurality of second digital signals into analog signals prior to transmission to the plurality of end devices.

4. The communication system of claim 3, wherein the remote unit is further configured to convert the plurality of second digital signals into the analog signals simultaneously using a single digital-to-analog converter.

5. The communication system of claim 4, wherein the analog-to-digital converter and the digital-to-analog converter have a resolution of at least 14 bits.

6. The communication system of claim 1, wherein the plurality of signals received at the remote unit are associated with at least one of a plurality of wired communication standards and a plurality of wireless communication standards, the plurality of wireless communication standards including at least one of a 3G communication standard, a 4G communication standard, a Universal Mobile Telecommunication System (UMTS) communication standard, and a Code Division Multiple Access (CDMA) communication standard.

7. The communication system of claim 1, wherein the remote unit and the central unit communicate via at least one of a wired communication link and a wireless communication link.

8. The communication system of claim 7, wherein the wired communication link is capable of transmitting data at a rate of at least 10 Giga bits per second (Gbps).

9. The communication system of claim 1, wherein the central unit is further configured to process the plurality of first digital signals by performing at least one of a digital signal processing, a media access control and a routing of the plurality of first digital signals to intended destinations.

10. The communication system of claim 1, wherein the remote unit is a base station.

11. A remote unit configured to,
convert a plurality of signals received at the remote unit into a plurality of first digital signals, regardless of a bandwidth occupied by any of the plurality of signals;
transmit the plurality of first digital signals to a central unit;
receive a plurality of second digital signals back from the central unit upon the central unit having processed the plurality of first digital signals; and
transmit the plurality of second digital signals to a plurality of end devices.

12. The remote unit of claim 11, wherein the remote unit does not include a hardware customized according to any given communication standard.

13. The remote unit of claim 12, wherein the remote unit is further configured to,
convert the plurality of signals into the plurality of first digital signals simultaneously using a single analog-to-digital convert, and
convert the plurality of second digital signals into analog signals simultaneously using a single digital-to-analog converter and prior to transmission to the plurality of end devices.

14. The remote unit of claim 13, wherein the analog-to-digital converter and the digital-to-analog converter have a resolution of at least 14 bits.

15. The remote unit of claim 12, wherein the remote unit is a base station.

16. The remote unit of claim 11, wherein the plurality of signals received at the remote unit are associated with at least one of a plurality of wired communication standards and a plurality of wireless communication standards, the plurality of wireless communication standards including at least one of a 3G communication standard, a 4G communication standard, a Universal Mobile Telecommunication System (UMTS) communication standard, and a Code Division Multiple Access (CDMA) communication standard.

17. A central unit comprising:
a processor configured to,
receive a plurality of first digital signals from a remote unit,
determine one of a plurality of communication standards according to which any one of the plurality of first digital signals is to be processed, and
enable processing of the one of the plurality of first digital signals based on the determined one of the plurality of communication standards.

18. The central unit of claim 17, wherein the plurality of communication standards include at least one of a plurality of wired communication standards and a plurality of wireless communication standards, the plurality of wireless communication standards including at least one of a 3G communication standard, a 4G communication standard, a Universal Mobile Telecommunication System (UMTS) communication standard, and a Code Division Multiple Access (CDMA) communication standard.

19. The central unit of claim 17, wherein the processor is further configured to determine one of the plurality of communication standards by enabling at least one of a modulation and demodulation of the plurality of first digital signals by the digital signal processing unit of the central unit, and
the processing includes at least one of a media access control and a routing of the plurality of first digital signals to intended destinations, by a central processing unit of the central unit.

20. The central unit of claim 17, wherein the processor is further configured to generate a plurality of second digital signals based on the processing of the plurality of first digital signals, the plurality of second digital signals being transmitted back to the remote unit for further transmission to end devices.
